(19) United States
(12) Patent Application Publication
(10) Pub. No.: US 2008/0135946 A1
(43) Pub. Date: Jun. 12, 2008

(54) Read only memory cell having multi-layer structure for storing charges and manufacturing method thereof

(75) Inventor: Shuo-Ting Yan, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 12/001,549

(22) Filed: Dec. 11, 2007

(30) Foreign Application Priority Data
Dec. 11, 2006 (TW) 95146230

(51) Int. Cl. H01L 27/112; H01L 21/336

(52) U.S. Cl. 257/390; 438/287; 257/E27.102; 257/E21.409

(57) ABSTRACT

An exemplary read only memory cell (200) includes a semiconductor layer (220), a gate stack (230), and a gate electrode (240). The gate stack includes a tunnel film (231), a charge storing layer (232), and a block layer (233) sequentially stacked adjacent to the semiconductor layer. The gate electrode is adjacent to the block layer. The charge storing layer is configured to store charges when data is written to the read only memory cell. The charge storing layer comprises at least two sub-layers having different molecular structures of material such that a plurality of interfacial traps is provided where the at least two sub-layers adjoin each other. A method for manufacturing the read only memory cell is also provided.

### FIELD OF THE INVENTION

The present invention relates to a read only memory cell having interfacial traps for storing charge, and a method for manufacturing such read only memory cell.

### GENERAL BACKGROUND

Read only memories can be used for storing data very conveniently, and thus they have become more and more popular. A typical read only memory includes a plurality of memory cells. Each of the memory cells can be used to store one bit of data.

FIG. 15 is a schematic, cross-sectional view of a conventional read only memory cell. The read only memory cell 100 has a typical configuration of an insulated gate field effect transistor (IGFET). The read only memory cell 100 includes a substrate 110, a semiconductor layer 120, a gate stack 130, and a gate electrode 140. The gate electrode 140, the gate stack 130, and the semiconductor layer 120 are disposed on the substrate 110 in that order from top to bottom.

The gate electrode 140 is disposed on a middle portion of a top surface of the gate stack 130, and is typically made of poly-silicon having a high doping concentration. The gate stack 130 includes a tunnel film 131, a charge storing layer 132, and a block layer 133, which are disposed between the gate electrode 140 and the semiconductor layer 120 in that order from bottom to top. The tunnel film 131 and the block layer 133 are both made of oxide. The charge storing layer 132 is a nitride layer, and includes a plurality of charge traps therein. Thereby, the gate stack 130 has an oxide-nitride-oxide (ONO) structure. The semiconductor layer 120 is made of silicon, and includes a first heavily doped region 121 and a second heavily doped region 122. The first heavily doped region 121 and the second heavily doped region 122 are respectively configured to be a source region and a drain region. The source region and the drain region are disposed within the semiconductor layer 120, corresponding to opposite sides of the gate electrode 140. Moreover, a region between the source region and the drain region defines a so-called channel region.

One bit of data can be written and stored into the read only memory cell 100 via a writing process. During the writing process, a writing signal (i.e. a positive voltage signal) is applied to the gate electrode 140, so as to form an electrical field between the gate electrode 140 and the semiconductor layer 120. The electrical field causes a plurality of unstable electrons to be generated in the channel region. If the writing signal is sufficiently great, the electrons obtain adequate energy such that a so-called Poole-Frenkel emission phenomenon takes place. That is, the electrons migrate toward the gate electrode 140, pass through the tunnel film 131, and then are captured by the charge traps and thereby stored in the charge storing layer 132. At the end of the writing process, the writing signal is stopped. Once the electrons are captured by the charge traps, they form an additive electrical field oriented from the channel region to the charge storing layer 132. The additive electrical field causes a threshold voltage of the read only memory cell 100 to be increased.

To simplify the following description, some definitions are provided herein. When no electrons are captured by the charge traps, the threshold voltage of the read only memory cell 100 is defined as a first threshold voltage. When electrons are captured by the charge traps, the elevated threshold voltage of the read only memory cell 100 is defined as a second threshold voltage.

In use of the read only memory cell 100, a driving voltage signal having a value between the first threshold voltage and the second threshold voltage may be applied to the gate electrode 140. When no electrons are captured by the charge traps, the driving voltage signal is sufficiently high to switch the read only memory cell 100 on, and the read only memory cell 100 accordingly provides a first signal (e.g. a low voltage signal). In contrast, when electrons are captured by the charge trap, the driving voltage signal is not high enough to be able to switch the read only memory cell 100 on. Thus the read only memory cell 100 remains in an off state, and accordingly provides a second signal (e.g. a high voltage signal). The first signal can be defined as ‘0’, and the second signal can be defined as ‘1’. Thus the read only memory cell 100 is capable of storing one bit of binary data, with the identity of the bit determined by the presence or absence of captured electrons.

Moreover, when the one bit of binary data is ‘1’, this data can be erased by applying an erasing signal (i.e. a sufficiently great negative voltage signal) to the read only memory cell 100. The negative voltage signal provides adequate energy for the captured electrons to escape from the charge traps. When the one bit of binary data ‘1’ is erased, there are no electrons captured in the charge traps. Therefore the threshold voltage of the read only memory cell 100 returns to the first threshold voltage.

In summary, the read only memory cell 100 stores the one bit of binary data ‘1’ by capturing electrons in the charge traps. However, the number of charge traps in the charge storing layer 132 is usually rather limited. This means the electron capturing efficiency is low, and accordingly a so-called memory window of the read only memory cell 100 is small.

The small memory window means that the difference between the first threshold voltage and the second threshold voltage is small. Thus a tolerance range of the driving voltage signal of the read only memory 100 is limited. For example, when electrons are captured in the charge traps, and the driving voltage signal is applied, the read only memory cell 100 should output a high voltage signal. However, in practice, the actual driving voltage signal may be unstable. For instance, the driving voltage signal may have a surge that is a little greater than the second threshold voltage. When this happens, the read only memory cell 100 may erroneously provide a low voltage signal. Because the tolerance range of the driving voltage signal is limited, the risk of the driving voltage signal exceeding the tolerance range is quite high, and accordingly the risk of the read only memory cell 100 outputting an erroneous signal is correspondingly high. In general, it is difficult to consistently control the driving voltage signal to be highly accurate and thereby stay within the tolerance range. Therefore, the reliability of the read only memory cell 100 is somewhat low.

It is, therefore, desired to provide a read only memory cell which overcomes the above-described deficiencies. A method for manufacturing such read only memory cell is also desired.

### SUMMARY

In a first aspect, a read only memory cell includes a semiconductor layer, a gate stack, and a gate electrode. The gate stack includes a tunnel film, a charge storing layer, and a block layer sequentially stacked adjacent to the semiconductor layer. The gate electrode is adjacent to the block layer. The charge storing layer is configured to store charges when data is written to the read only memory cell. The charge storing layer includes at least two sub-layers having different molecular structures of material such that a plurality of interfacial traps is provided where the at least two sub-layers adjoin each other.

In a second aspect, a method for manufacturing a read only memory cell includes: providing a substrate; providing a semiconductor layer on the substrate; forming a tunnel film on the semiconductor layer; forming a charge storing layer on the tunnel film, which includes at least two sub-layers having different molecular structures of material such that a plurality of interfacial traps is formed where the at least two sub-layers adjoin each other; forming a block layer on the charge storing layer; and forming a gate electrode on the block layer.

In a third aspect, a method for manufacturing a read only memory cell includes: providing a substrate; forming a gate electrode on the substrate; forming a block layer on the gate electrode; forming a charge storing layer on the block layer, which includes at least two sub-layers having different molecular structures of material such that a plurality of interfacial traps is formed where the at least two sub-layers adjoin each other; forming a tunnel film on the charge storing layer; and forming a semiconductor layer on the tunnel film.

Other novel features and advantages will become more apparent from the following detailed description when taken in conjunction with the accompanying drawings. In the drawings, all the views are schematic.

### BRIEF DESCRIPTION OF THE DRAWINGS

FIG. 1 is a schematic, cross-sectional view of a read only memory cell according to a first exemplary embodiment of the present invention.

FIG. 2 is a flow chart of an exemplary method for manufacturing the read only memory cell of FIG. 1, the method including steps S1, S2, S3, S4, and S5.

FIG. 3 is schematic, cross-sectional view of a stage of providing a substrate in accordance with step S1 of the method of FIG. 2.

FIG. 4 is a schematic, cross-sectional view of a stage of forming a semiconductor layer in accordance with step S2 of the method of FIG. 2.

FIG. 5 is a flow chart of details of step S3 of the method of FIG. 2, step S3 including sub-steps S31, S32, and S33.

FIG. 6 is a schematic, cross-sectional view of a stage of forming a tunnel film in accordance with sub-step S31 of step S3 of the method of FIG. 2.

FIGS. 7 to 9 are schematic, sectional views of sequential sub-stages of forming a charging storing layer having a multi-layer structure in accordance with sub-step S32 of step S3 of the method of FIG. 2.

FIG. 10 is a schematic, cross-sectional view of a stage of forming a block layer in accordance with sub-step S33 of step S3 of the method of FIG. 2.

FIG. 11 is a schematic, cross-sectional view of a stage of forming a gate electrode in accordance with step S4 of the method of FIG. 2.

FIG. 12 is a schematic, cross-sectional view of a stage of forming two heavily doped regions in accordance with step S5 of the method of FIG. 2.

FIG. 13 is a schematic, cross-sectional view of a read only memory cell according to a second exemplary embodiment of the present invention.

FIG. 14 is a flow chart of an exemplary method for manufacturing the read only memory cell of FIG. 13.

FIG. 15 is a schematic, cross-sectional view of a conventional read only memory cell.

### DETAILED DESCRIPTION OF PREFERRED EMBODIMENTS

Reference will now be made to the drawings to describe preferred and exemplary embodiments of the present invention in detail.

FIG. 1 is a schematic, cross-sectional view of a read only memory cell 200 according to a first exemplary embodiment of the present invention. The read only memory cell 200 is a unit element of a read only memory, and has a typical configuration of a top-gate type insulated gate field effect transistor (IGFET). The read only memory cell 200 includes a substrate 210, a semiconductor layer 220, a gate stack 230, and a gate electrode 240. The semiconductor layer 220, the gate stack 230, and the gate electrode 240 are disposed on the substrate 210 in that order from bottom to top.

The substrate 210 is configured for supporting the semiconductor layer 220, the gate stack 230, and the gate electrode 240 thereon. The substrate 210 can be a silicon substrate or a glass substrate.

The semiconductor layer 220 is made of silicon, preferably poly-silicon. A thickness of the semiconductor layer 220 is in a range from 30 nanometers (nm) to 100 nm. The semiconductor layer 220 includes a first heavily doped region 221 and a second heavily doped region 222, both of which are doped with dopants. The first heavily doped region 221 and the second heavily doped region 222 are respectively configured to be a source region and a drain region, and are disposed within the semiconductor layer 220 at positions corresponding to opposite sides of the gate electrode 240 respectively. A region between the source region and the drain region defines a so-called channel region. The dopants that are doped into the first heavily doped region 221 and the second heavily doped region 222 can for example be phosphorus ions or arsenic ions.

The gate stack 230 includes a tunnel film 231, a charge storing layer 232, and a block layer 233 disposed in that order from bottom to top. The tunnel film 231 is made of oxide such as silicon dioxide (SiO₂). A thickness of the tunnel film 231 is in a range from 5 nm to 10 nm. The charge storing layer 232 is in a sandwich-like structure, and is made of nitride such as silicon nitride (SiNx). The charge storing layer 232 includes a first nitride layer 234, a second nitride layer 235, and a third nitride layer 236, which are disposed on the tunnel film 231 in that order from bottom to top. A thickness of the charge storing layer 232 is in a range from 30 nm to 110 nm. In particular, a thickness of the first nitride layer 234 is in a range from 10 nm to 30 nm, a thickness of the second nitride layer 235 is in a range from 10 nm to 50 nm, and a thickness of the third layer 236 is in a range from 10 nm to 30 nm.

Each of the nitride layers 234, 235, 236 includes a plurality of charge traps therein for capturing charge elements such as electrons. The charge traps can be obtained via forming the SiNx in a chemical reaction of ammonia (NH₃) and silane (SiH₄), or in a chemical reaction of NH₃, SiH₄, and nitrous oxide (N₂O). During the process of manufacturing the nitride layers 234, 235, 236, extraneous elements such as oxygen and hydrogen inevitably enter the nitride layers 234, 235, 236 and stay therein. These impurities break covalent bonds of SiNx, such that a plurality of charge traps are generated in each of the nitride layers 234, 235, 236.

Furthermore, in the charge storing layer 232, molecular structures of the SiNx in the nitride layers 234, 235, 236 are different from each other. Due to the differences in the molecular structures, a plurality of unsaturated dangling bonds are provided in the SiNx molecules that are at a transition region (not labeled) between the first nitride layer 234 and the second nitride layer 235, and another plurality of unsaturated dangling bonds are also provided at another transition region (not labeled) between the second nitride layer 235 and the third nitride layer 236. The dangling bonds are also capable of capturing charge elements such as electrons. That is, these dangling bonds provide a plurality of interfacial traps in SiNx-SiNx interfaces. The interfacial traps function as charge traps in each of the nitride layers 234, 235, 236, for capturing electrons. Moreover, due to the differences in the molecular structures, the modes in which neighboring SiNx molecules of the nitride layers 234, 235, 236 combine are also different. This further causes more dangling bonds to be generated in SiNx-SiNx interfaces, which dangling bonds provide a plurality of interfacial traps. The above-stated differences in molecular structures and the corresponding differences in modes in which neighboring SiNx molecules combine can be attained in the nitride layers 234, 235, 236 by providing different conditions during the processes of forming the nitride layers 234, 235, 236.

The block layer 233 is also made of oxide such as silicon dioxide. A thickness of the block layer 233 is in a range from 30 nm to 70 nm. Thereby, the gate stack 230 has an oxide-nitride-nitride-nitride-oxide (ONNNO) structure. The gate electrode 240 is disposed on a middle portion of a top surface of the gate stack 230. The gate electrode 240 can be made of poly-silicon having a high doping concentration. Alternatively, the gate electrode 240 can be made of metal having low electrical resistivity, such as one of aluminum, copper, chromium, and tungsten. A thickness of the gate electrode 240 is in a range from 200 nm to 500 nm.

One bit of data can be written and stored into the read only memory cell 200 via a writing process, and this 1-bit data can also be erased from the read only memory cell 200 via an erasing process.

During the writing process, a writing signal (i.e. a positive voltage signal) is applied to the gate electrode 240, so as to form a first electrical field orientating from the gate electrode 240 to the semiconductor layer 220. The first electrical field causes a plurality of unstable electrons to be generated in the channel region. If the voltage signal is sufficiently great (for example, 20V (volts)), the electrons obtain adequate energy from the first electrical field. In this situation, a so-called Pool-Frenkel emission phenomenon takes place. That is, the electrons migrate from the channel region, pass through the tunnel film 231, and arrive at the charge storing layer 232. In the charge storing layer 232, a proportion of the electrons are captured by the charge traps in the nitride layers 234, 235, 236, and another proportion of the electrons are captured by the interfacial traps in the SiNx-SiNx interfaces. At the end of the writing process, the writing signal is stopped.

Once the electrons are captured by the charge traps and the interfacial traps, they form an additive electrical field oriented from the channel region to the charge storing layer 232. The additive electrical field causes a threshold voltage of the read only memory cell 200 to be increased.

To simplify the following description, some definitions are provided herein. When no electrons are captured by the charge traps, the threshold voltage of the read only memory cell 100 is defined as a first threshold voltage. When electrons are captured by the charge traps, the elevated threshold voltage of the read only memory cell 100 is defined as a second threshold voltage.

In use of the read only memory cell 100, a driving voltage signal having a value between the first threshold voltage and the second threshold voltage may be applied to the gate electrode 240. When no electrons are captured by the charge trap, the driving voltage signal is sufficiently high to switch the read only memory cell 200 on, and the read only memory cell 200 accordingly provides a first signal (e.g. a low voltage signal). In contrast, when the unstable electrons are captured in the charge storing layer 232, the driving voltage signal is not high enough to be able to switch the read only memory cell 200 on. Thus the read only memory cell 200 remains in an off state, and accordingly provides a second signal (e.g. a high voltage signal). The first signal can be defined as ‘0’, and the second signal can be defined as ‘1’. Thus the read only memory cell 200 is capable of storing one bit of binary data, with the identity of the bit determined by the presence or absence of captured electrons.

Conversely, during the erasing process, an erasing signal (i.e. a negative voltage signal (for example, −20V)) is applied to the gate electrode 240, so as to form a second electrical field orientated from the semiconductor layer 220 to the gate electrode 240. The second electrical field causes a plurality of holes to be generated in the channel region, and provides energy for the captured electrons captured by the charge traps and the interfacial traps. The captured electrons obtain adequate energy from the second electrical field, and escape from the charge storing layer 232. In detail, the captured electrons migrate toward the semiconductor layer 220, pass through the tunnel film 231, and then recombine with the holes in the channel region and disappear. Thus the one bit of data ‘1’ is erased from the read only memory cell 200. When the one bit of data ‘1’ is erased, there are no electrons captured in the charge storing layer 232. Therefore, the threshold voltage of the read only memory cell 200 returns to the first threshold voltage. In this situation, when the above-described driving voltage is applied to the read only memory cell 200, the read only memory cell 200 provides a low voltage.

During the erasing process, positive voltage signals (for example, 10V) can be applied to both the source region 221 and the drain region 222 in the semiconductor layer 220. Thereby the electrons in the charge storing layer 232 can pass through the tunnel film 231, and then are transmitted away via the source region 221 and the drain region 222. With this positive voltage signal, the erasing speed can be increased.

The gate stack 230 of the read only memory cell 200 is configured to have the ONNNO structure, and a plurality of interfacial traps capable of capturing electrons are provided at the SiNx-SiNx interfaces. Thereby, the electron capturing efficiency is improved, and the memory window of the read only memory cell 200 is increased. Thus the difference between the first threshold voltage and the second threshold voltage is increased, and a tolerance range of the driving voltage signal of the read only memory 200 is expanded. Even if the driving voltage signal is somewhat unstable, the possibility of the read only memory cell 200 providing an erroneous signal is reduced. As a result, the read only memory cell 200 has improved reliability.

In alternative embodiments, the gate stack 230 of the read only memory cell 200 can be configured to an ONNO structure, with the charge storing layer 232 including two nitride layers. The charge storing layer 232 can be configured to be a multi-layer structure having four or even more nitride layers. The charge storing layer 232 can be made of other material having charge traps therein, such as aluminum oxide (AlOx), silicon carbon nitride (SiCN), silicon nitride oxide (SiNO), silicon carbon (SiC), silicon carbon oxide (SiCO), silicon carbon oxide nitride (SiCON), hafnium oxide nitride (HfON), and the like. The charge storing layer 232 can further have at least two sub-layers having different material, as long as the molecular structures of the at least two sub-layers are different such that interfacial traps are formed. In particular, the charge storing layer 232 can include an SiNx layer, and an AlOx layer disposed on the SiNx layer.

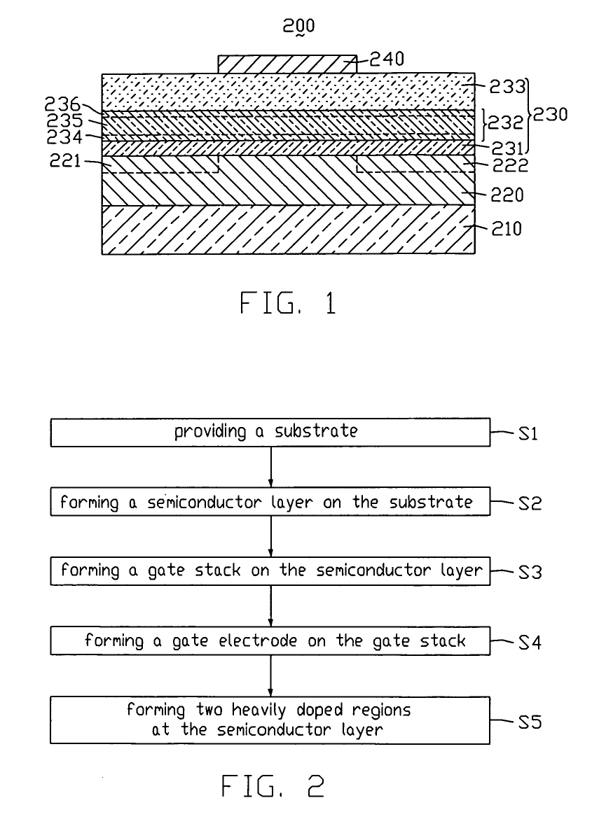

FIG. 2 is a flow chart of an exemplary method for manufacturing the read only memory cell 200. The method includes the following steps: S1, providing a substrate; S2, forming a semiconductor layer on the substrate; S3, forming a gate stack on the semiconductor layer; S4, forming a gate electrode on the gate stack; and S5, forming two heavily doped regions at the semiconductor layer.

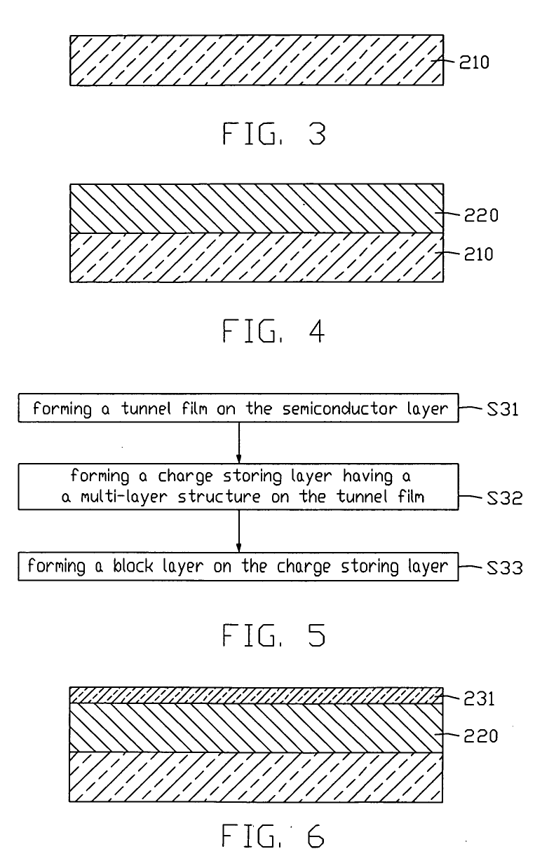

Referring to FIG. 3, in step S1, the substrate 210 is provided. The substrate 210 is made of silicon or glass.

Referring to FIG. 4, in step S2, a semiconductor layer 220 is formed on the substrate 210, and the semiconductor layer 220 is made of poly-silicon. The semiconductor layer 220 can be formed via one of the following three methods. First, the poly-silicon layer directly is formed via a chemical vapor deposition (CVD) method. Second, an amorphous silicon layer is formed via the CVD method, and then the amorphous silicon layer is converted into the poly-silicon layer via an excimer laser annealing (ELA) method. Third, an amorphous silicon layer is formed via a CVD method, and then the amorphous silicon layer is converted into the poly-silicon layer via a heating process. In the heating process, the processing temperature is in a range from 500° C. (degree Celsius) to 600° C.

FIG. 5 is flow chart of details of step S3 of the exemplary method for manufacturing the read only memory cell 200. Step S3 includes the following steps: S31, forming a tunnel film on the semiconductor layer; S32, forming a charge storing layer having a multi-layer structure on the tunnel film; and S33, forming a block layer on the charge storing layer.

Referring to FIG. 6, in step S31, the tunnel film 231 is formed on the semiconductor layer 220 via the CVD method, and the tunnel film 231 is made of silicon dioxide (SiO₂).

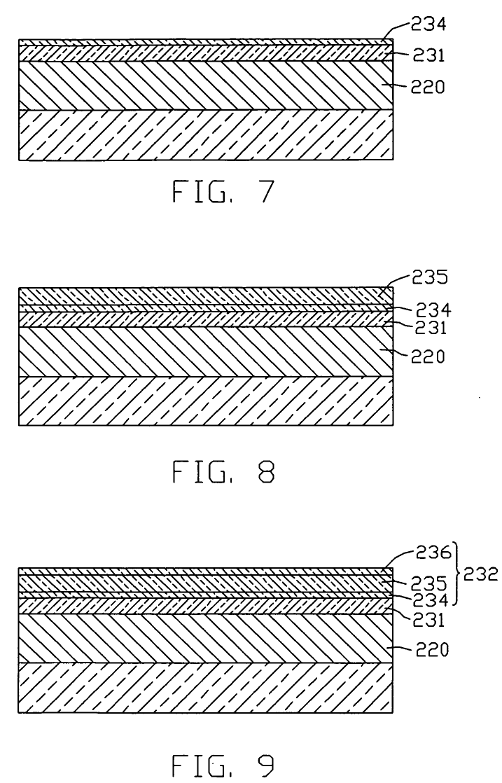

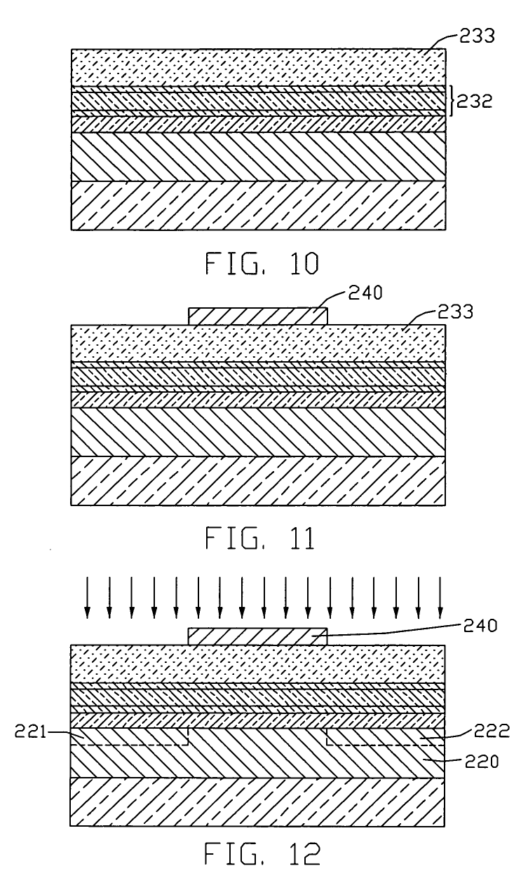

Referring to FIGS. 7-9, in step S32, firstly, the first nitride layer 234 is formed on the tunnel film 231 via a plasma enhanced chemical vapor deposition (PECVD) method with a first deposition speed. Secondly, the second nitride layer 235 is formed on the first nitride layer 234 via the PECVD method with a second deposition speed. Thirdly, the third nitride layer 236 is formed on the second nitride layer 235 via the PECVD method with a third deposition speed. The first, second, and third deposition speeds are different, in particular, the second deposition speed is the greatest, and the third deposition speed is greater than the first deposition speed. Moreover, the nitride layers 234, 235, 236 are made of SiNx, and can made via chemical reaction of ammonia (NH₃) and silane (SiH₄), or via chemical reaction of NH₃, SiH₄, and nitrous oxide (N₂O). After step S32, the charge storing layer 232 having a multi-layer structure is formed on the tunnel film 231.

Because the first nitride layer 234, the second nitride layer 235, and the third nitride layer 236 are formed via different deposition speeds, the molecular structure of a single SiNx molecule and the combining mode of two neighboring SiNx molecules of each of the nitride layers 234, 235, 236 are both different from that of the other nitride layers 234, 235, 236. Thus a plurality of interfacial traps are formed in the transition regions between every two of the nitride layers 234, 235, 236.

Referring to FIG. 10, in step S33, the block layer 233 is formed on the charge storing layer 232 via the CVD method, and the block layer 231 is also made of SiO2. After step S33, the gate stack 230 including the tunnel film 231, the charge storing layer 232, and the block layer 233 is formed on the semiconductor layer 220, and has an ONNNO structure.

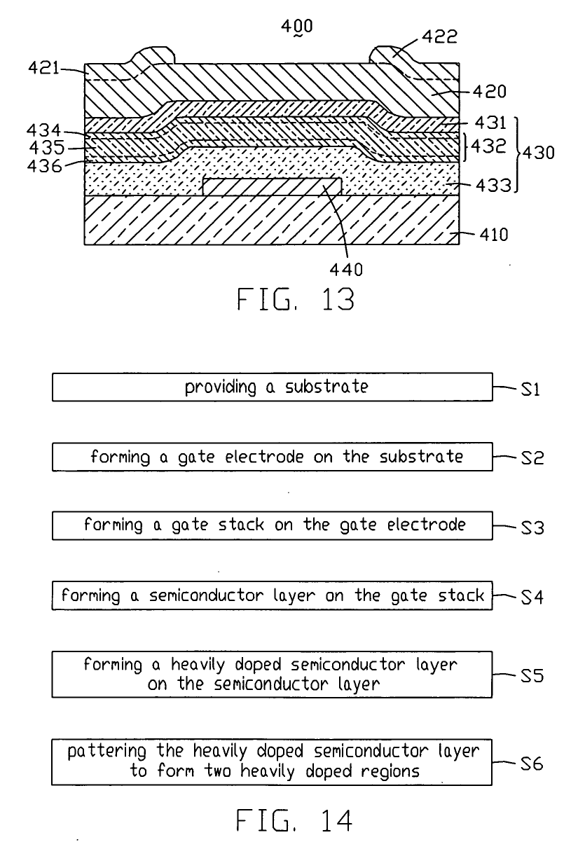

Referring to FIG. 11, in step S4, firstly, the gate electrode layer is formed on the block layer 233. The gate electrode layer can be made of metal having a low resistivity, such as a selected one of aluminum, copper, chromium, and tungsten; and are formed via a physical vapor deposition (PVD) method such as sputtering or evaporation. The gate electrode layer can also be made of poly-silicon, and formed via a selected one of the methods of forming the semiconductor layer 220 in step S2, then are doped with dopant having a high doping concentration. Secondly, the gate electrode layer is patterned via photolithography, so as to form the gate electrode 240 at the middle of the block layer 233.

Referring to FIG. 12, in step S5, two heavily doped regions 221, 222 is formed in the semiconductor layer 220 via ion implantation. In detail, phosphorus ions or arsenic ions are implanted into the semiconductor layer 220 via self-aligned technology. That is, the gate electrode 240 serves as a mask in this step to prevent the ions from entering a channel region in the semiconductor layer 220 that is opposite to the gate electrode 240. Thus after such implantation, two heavily doped regions 221, 222 are formed at opposite sides of the gate electrode 240 within the semiconductor layer 220.

In the method for manufacturing the manufacturing the read only memory cell 200, the charge storing layer 232 is formed via providing multiple manufacturing conditions, such that the charging storing layer 232 is formed as a multi-layer structure. In detail, the first nitride layer 234, the second nitride layer 235, and the third nitride layer 236 are formed via different deposition speeds, thus the physical characteristics of the nitride layers 234, 235, 236 are different. This causes the SiNx-SiNx interfaces to provide a plurality of interfacial traps that can capture electrons. Therefore, in the read only memory cell 200 that is manufactured via such method, the electron capturing efficiency is improved, and the memory window is increased. As a result, the reliability of the read only memory cell 200 is improved.

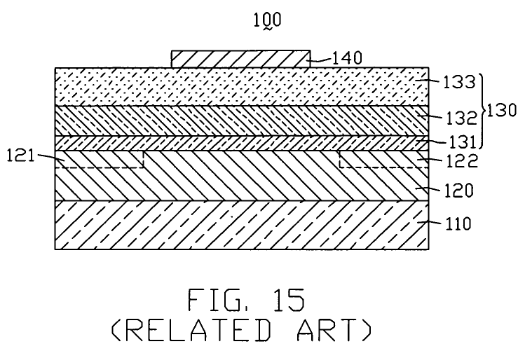

FIG. 13 is a schematic, cross-sectional view of a read only memory cell 400 according to a second exemplary embodiment of the present invention. The read only memory cell 400 is similar to the read only memory cell 200. However, the read only memory cell 400 has a typical configuration of a bottom-gate type insulated gate field effect transistor (IGFET). The read only memory cell 400 includes a substrate 410, a gate electrode 440, a gate stack 430, and a semiconductor layer 420.

The gate electrode 440 is disposed at the middle of the substrate 410. The gate stack 430 includes a block layer 433, a charge storing layer 432, and a tunnel film 431 disposed on the gate electrode 440 in that order from bottom to top. The charge storing layer 432 includes a first nitride layer 436, a second nitride layer 435, and a third nitride layer 434 in that order from bottom to top. The semiconductor layer 420 is disposed on the tunnel film 431, and includes a source region 421 and a drain region 422. The source region 421 and the drain region 422 are disposed within the semiconductor layer 120 and corresponding to opposite sides of the gate electrode 140

FIG. 14 is a flow chart of an exemplary method for manufacturing the read only memory cell 400 of FIG. 13. The method includes the following steps: S1, providing a substrate; S2, forming a gate electrode on the substrate; S3, forming a gate stack on the gate electrode; S4, forming a semiconductor layer on the gate stack; S5, forming a heavily doped semiconductor layer on the semiconductor layer; and S6, pattering the heavily doped semiconductor layer and form two heavily doped regions.

In step S1, the substrate 410 is provided. In step S2, the gate electrode 440 is formed at the middle of the substrate 410. Step S3 including the following sub-steps: forming a block layer 433 on the gate electrode 440; forming a charge storing layer 432 having a multi-layer structure on the block layer 433; and forming the tunnel film 431 on the charge storing layer 432. Moreover, detail of forming the charge storing layer 432 is as follows: firstly, forming the first nitride layer 436 on the block layer via the PECVD method with a first deposition speed; forming a second nitride layer 435 on the first nitride layer via the PECVD method with a second deposition speed; and forming a third nitride layer 434 on the second nitride layer via the PECVD method with a third deposition speed. The first nitride layer, the second nitride layer, and the third nitride layer are formed to be silicon nitride (SiNx). In step S4, the semiconductor layer 420 is formed on the tunnel film 431. In step S5, the surface portion of the semiconductor layer 420 is doped, so as to form a heavily doped semiconductor layer. In step S6, the heavily doped semiconductor layer is patterned, and two heavily doped regions 421, 422 are formed on the surface of the semiconductor layer 420.

In addition, all the above-described manufacturing technology of the method for manufacturing the read only memory cell 200 can be also employed in the method for manufacturing the read only memory cell 400.

It is to be further understood that even though numerous characteristics and advantages of preferred and exemplary embodiments have been set out in the foregoing description, together with details of the structures and functions of the embodiments, the disclosure is illustrative only; and that changes may be made in detail within the principles of the present invention to the full extent indicated by the broad general meaning of the terms in which the appended claims are expressed.

What is claimed is:

1. A read only memory cell, comprising:
a semiconductor layer;
a gate stack comprising a tunnel film, a charge storing layer, and a block layer sequentially stacked adjacent to the semiconductor layer; and
a gate electrode adjacent to the block layer;
wherein the charge storing layer is configured to store charge when data is written to the read only memory cell, and the charge storing layer comprises at least two sub-layers having different molecular structures of material such that a plurality of interfacial traps is provided where the at least two sub-layers adjoin each other.

2. The read only memory cell as claimed in claim 1, wherein the at least two sub-layers further have different modes in which two neighboring molecules combine.

3. The read only memory cell as claimed in claim 1, wherein the material of the charge storing layer comprises a selected one of silicon nitride (SiNx), aluminum oxide (AlOx), aluminum oxide (AlOx), silicon carbon nitride (SiCN), silicon nitride oxide (SiNO), silicon carbon (SiC), silicon carbon oxide (SiCO), silicon carbon oxide nitride (SiCON), and hafnium oxide nitride (HfON).

4. The read only memory cell as claimed in claim 1, wherein the at least two sub-layers are three sub-layers, which comprise a first sub-layer, a second sub-layer, and a third sub-layer sequentially stacked.

5. The read only memory cell as claimed in claim 4, wherein a thickness of the first sub-layer is in a range from 10 nanometers to 30 nanometers.

6. The read only memory cell as claimed in claim 5, wherein a thickness of the second sub-layer is in a range from 10 nanometers to 50 nanometers.

7. The read only memory cell as claimed in claim 1, wherein a thickness of the charge storing layer is in a range from 30 nanometers to 110 nanometers.

8. The read only memory cell as claimed in claim 1, wherein the read only memory cell has a configuration of a top-gate type insulated gate field effect transistor or a bottom-gate type insulated gate field effect transistor.

9. A method for manufacturing a read only memory cell, the method comprising:
providing a substrate;
providing a semiconductor layer on the substrate;
forming a tunnel film on the semiconductor layer;
forming a charge storing layer on the tunnel film, which comprises at least two sub-layers having different molecular structures of material such that a plurality of interfacial traps is formed where the at least two sub-layers adjoin each other;
forming a block layer on the charge storing layer; and
forming a gate electrode on the block layer.

10. The method for manufacturing a read only memory cell as claimed in claim 9, wherein the at least two sub-layers are formed via providing at least two manufacturing conditions.

11. The method for manufacturing a read only memory cell as claimed in claim 9, wherein the charge storing layer comprises three sub-layers.

12. The method for manufacturing a read only memory cell as claimed in claim 11, wherein forming a charge storing layer on the tunnel film comprises: forming a first sub-layer on the tunnel film via a chemical vapor deposition method with a first deposition speed; forming a second sub-layer on the first sub-layer via the chemical vapor deposition method with a second deposition speed; and forming a third sub-layer on the second sub-layer via the chemical vapor deposition method with a third deposition speed.

13. The method for manufacturing a read only memory cell as claimed in claim 12, wherein the first, second, and third first deposition speeds are different from each other.

14. The method for manufacturing a read only memory cell as claimed in claim 12, wherein a thickness of the first sub-layer is in a range from 10 nanometers to 30 nanometers, and a thickness of the second sub-layer is in a range from 10 nanometers to 50 nanometers.

15. The method for manufacturing a read only memory cell as claimed in claim 9, wherein a thickness of the charge storing layer is in a range from 30 nanometers to 110 nanometers.

16. The method for manufacturing a read only memory cell as claimed in claim 9, wherein each of at least two sub-layers comprises a selected one of silicon nitride (SiNx), aluminum oxide (AlOx), aluminum oxide (AlOx), silicon carbon nitride (SiCN), silicon nitride oxide (SiNO), silicon carbon (SiC), silicon carbon oxide (SiCO), silicon carbon oxide nitride (SiCON), and hafnium oxide nitride (HfON).

17. A method for manufacturing a read only memory cell, the method comprising:
providing a substrate;
forming a gate electrode on the substrate;
forming a block layer on the gate electrode;
forming a charge storing layer on the block layer, which comprises at least two sub-layers having different molecular structures of material such that a plurality of interfacial traps is formed where the at least two sub-layers adjoin each other;
forming a tunnel film on the charge storing layer; and
forming a semiconductor layer on the tunnel film.

18. The method for manufacturing a read only memory cell as claimed in claim 17, wherein the at least two sub-layers are formed via providing at least two manufacturing conditions.

19. The method for manufacturing a read only memory cell as claimed in claim 17, wherein each of the at least two sub-layers comprises a selected one of silicon nitride (SiNx), aluminum oxide (AlOx), aluminum oxide (AlOx), silicon carbon nitride (SiCN), silicon nitride oxide (SiNO), silicon carbon (SiC), silicon carbon oxide (SiCO), silicon carbon oxide nitride (SiCON), and hafnium oxide nitride (HfON).

20. The method for manufacturing a read only memory cell as claimed in claim 17, wherein forming a charge storing layer on the tunnel film comprises: forming a first sub-layer on the block layer via a chemical vapor deposition method with a first deposition speed; forming a second sub-layer on the first nitride layer via the chemical vapor deposition method with a second deposition speed; and forming a third sub-layer on the second nitride layer via the chemical vapor deposition method with a third deposition speed.
